(19) United States
(12) Patent Application Publication
(10) Pub. No.: US 2026/0202885 A1
(43) Pub. Date: Jul. 16, 2026

(54) DENSITY-OPTIMIZED COMPUTE SERVER

(71) Applicant: Lenovo Global Technology (UnitedStates) Inc., Morrisville, NC (US)

(72) Inventor: Timothy Glen Hanna, Apex, NC (US)

(21) Appl. No.: 19/022,159

(22) Filed: Jan. 15, 2025

(51) Int. Cl. G06F 1/18; H05K 7/20

(52) U.S. Cl. CPC G06F 1/184; H05K 7/20154; H05K 7/20409

(57) ABSTRACT

A system includes a system board having top and bottom surfaces, a processor socket positioned on the top surface of the system board, a first set of memory module sockets positioned on the top surface of the system board, and a second set of memory module sockets positioned on the bottom surface of the system board, wherein the processor socket is connected to each of the memory module sockets in the first and second sets of memory module sockets by a memory channel. The system further includes a processor installed in the processor socket, a first plurality of dual in-line memory modules installed in the first set of memory module sockets; and a second plurality of dual in-line memory modules installed in the second set of memory module sockets. In one option, each of the dual in-line memory modules may be double data rate 5 (DDR5) memory modules.

### BACKGROUND

The present disclosure relates to the physical configuration of rack mounted servers.

### Background of the Related Art

The next generation of processors include an increasing number of cores with a corresponding increase in the width of the processor socket and the Keep-Out Zone (KOZ) around the processor socket. These next generation processors also support more memory channels per processor socket 20. All of these developments require more area on the system board, such as a greater system board width. Furthermore, the greater amount of heat generated by these high performance processors and memory modules require a greater amount of cooling capacity and/or efficiency. However, these demands need to be met within the constraints of the installed base of 19 inch racks that are already in a majority of datacenters.

### BRIEF SUMMARY

Some embodiments provide a system comprising a first system board having a top surface and a bottom surface, a first processor socket positioned on the top surface of the first system board, a first set of memory module sockets positioned on the top surface of the first system board, and a second set of memory module sockets positioned on the bottom surface of the first system board, wherein the first processor socket is connected to each of the memory module sockets in the first and second sets of memory module sockets by a plurality of memory channels corresponding respectively to the memory module sockets. The system further comprises a first processor installed in the first processor socket, a first plurality of dual in-line memory modules installed in the first set of memory module sockets, and a second plurality of dual in-line memory modules installed in the second set of memory module sockets. In one option, each of the dual in-line memory modules may be double data rate 5 (DDR5) memory modules.

### BRIEF DESCRIPTION OF THE SEVERAL VIEWS OF THE DRAWINGS

FIG. 1A is a schematic diagram of a platform including a processor socket and a processor that support 16 memory channels and expanded input/output capabilities.

FIG. 1B is a diagram illustrating a dual socket system supporting 16 memory channels per socket superimposed over a system board that fits in a 19 inch rack chassis.

FIG. 2 is a plan view of a single socket system board supporting 16 memory channels/memory sockets per processor socket, including 8 memory module sockets on the top surface of the system board and 8 memory module sockets on the bottom surface of the system board.

FIG. 3 is an end view of the single socket system board showing the bottom memory module sockets offset from the top memory module sockets.

FIG. 4 is a schematic diagram illustrating the routing of 16 memory channels from the processor socket to each of the 16 memory module sockets.

FIG. 5 is a perspective view of a single sled including a system board, heat sink assembly and other supporting components secured in a tray.

FIG. 6A is a cross-section view of the sled taking along lines 6A-6A in FIG. 5.

FIG. 6B is a front end view of the sled.

FIG. 7 is a perspective view of a chassis including a fan bay, power bay and two sled bays.

FIG. 8 is a perspective view of the chassis of FIG. 7 after two sleds of FIG. 5 have been installed within the two sled bays.

FIG. 9 is a rear perspective view of the interconnection formed between the two sleds through a power distribution board using vertical backplane boards and the power connection of each sled to the power distribution board using a power interposer board.

FIG. 10 is a rear perspective view of the interconnection formed between the two sleds through a panel-mounted cable and the power connection of each sled to the power distribution board using a power interposer board.

### DETAILED DESCRIPTION

Some embodiments provide a system comprising a first system board having a top surface and a bottom surface, a first processor socket positioned on the top surface of the first system board, a first set of memory module sockets positioned on the top surface of the first system board, and a second set of memory module sockets positioned on the bottom surface of the first system board, wherein the first processor socket is connected to each of the memory module sockets in the first and second sets of memory module sockets by a plurality of memory channels corresponding respectively to the memory module sockets. The system further comprises a first processor installed in the first processor socket, a first plurality of dual in-line memory modules installed in the first set of memory module sockets, and a second plurality of dual in-line memory modules installed in the second set of memory module sockets. In one option, each of the dual in-line memory modules may be double data rate 5 (DDR5) memory modules.

In some embodiments, the first set of memory module sockets include eight memory module sockets, the second set of memory module sockets include eight memory module sockets, and the first processor socket is connected to the memory module sockets in the first and second sets of memory module sockets by sixteen memory channels. Accordingly, each memory module socket may be connected to the first processor socket by a separate one of the memory channels. In one option, the first system board includes 2 to 8 memory routing layers, and wherein each memory channel between the first processor socket and the first and second sets of memory module sockets is routed in one or the memory routing layers of the first system board. For example, four of the memory module sockets in the first set may be positioned on a first lateral side of the first processor socket, four of the memory module sockets in the first set may be positioned on a second lateral side of the first processor socket that is opposite of the first lateral side of the first processor, four of the memory module sockets in the second set may be positioned on the first lateral side of the first processor socket, and four of the memory module sockets in the second set may be positioned on the second lateral side of the first processor socket.

In some embodiments, the system board includes eight memory routing layers and sixteen memory channels. Optionally, four top memory routing layers may each route one of the memory channels to one of the memory module sockets in the first set on the first lateral side of the first processor socket and to one of the memory module sockets in the first set on the second lateral side of the first processor socket. Furthermore, four lower memory routing layers may each route one of the memory channels to one of the memory module sockets in the second set on the first lateral side of the first processor socket and one of the memory module sockets in the second set on the second lateral side of the first processor socket.

In some embodiments, the second set of memory module sockets are laterally offset from the first set of memory module sockets. For example, the first and second sets of memory module sockets may be positioned on the system board in a pattern alternating between the top and bottom surfaces of the system board with increasing distance from the first processor socket. In other words, if there are a total of eight memory module sockets to one lateral side of the processor socket, the alternating pattern may position the eight memory module sockets, in order with increasing distance from the processor socket, on the (1) top surface, (2) bottom surface, (3) top surface, (4) bottom surface, (5) top surface, (6) bottom surface, (7) top surface, and (8) bottom surface. Alternatively, the alternating pattern may place the eight memory module sockets on the (1) bottom surface, (2) top surface, (3) bottom surface, (4) top surface, (5) bottom surface, (6) top surface, (7) bottom surface, and (8) top surface.

In some embodiments, the memory module sockets in the first set of memory module sockets are positioned in parallel with a predetermined pitch on the top surface, the memory module sockets in the second set of memory module sockets are positioned in parallel with the predetermined pitch on the bottom surface, and the second set of memory module sockets are laterally offset from the first set of memory module sockets by a distance of half the predetermined pitch. Additionally, the memory module sockets are preferably oriented perpendicular to the first system board, such that the memory modules received in the memory module sockets will also be perpendicular to the first system board.

In some embodiments, the apparatus may further comprise a first tray having a bottom panel, a right side panel and a left side panel. The first system board is positioned between the right and left side panels and secured to the bottom panel of the first tray using a first plurality of spacers that position the first system board above the bottom panel at a distance that accommodates the second plurality of dual in-line memory modules installed in the second set of memory module sockets. In other words, the system board is “floated” at about mid-point of a chassis bay (“sled bay”) where the tray is receivable. For example, a sled that includes the first tray, the first system board, the memory modules and all other components secured to the first system board may be a double height sled and the first system board may be positioned mid-way or half-way between the bottom and top of the double height sled. As a result, the first system board may be approximately centered from top to bottom within the sled bay when the sled is received within the sled bay. The first system board may be secured in this elevated position using fasteners and spacers extending upward from the bottom of the chassis. Optionally, a motherboard tray may be supported by the spaces and disposed to provide support and stiffness to the first system board. Installing memory modules (DIMMs) with a standard form factor on the top and bottom of the first system board requires a 2U chassis with a 2U sled bay.

In some embodiments, the apparatus further comprises a heat sink assembly for removing heat from the processor. In one option, the heat sink assembly may comprise a heat sink in thermal contact with the first processor, first and second sets of remote heat transfer fins, and first and second heat pipes. The first heat pipe includes a first end connected to the heat sink and a second end connected to the first set of remote heat transfer fins. Similarly, the second heat pipe includes a first end connected to the heat sink and a second end connected to the second set of remote heat transfer fins. In a further option, the first and second sets of remote heat transfer fins may be positioned in the first tray forward of the system board and include double height fins that extend both above and below the level of the system board. The first and second sets of remote heat transfer fins are preferably positioned to avoid being directly in front (i.e., upstream relative to an air flow direction) of the heat sink that is in thermal contact with the first processor. For example, where the heat sink and first processor are centered from left to right on the first system board, the first set of remote heat transfer fins are preferably positioned adjacent to the right side panel of the first tray and the second set of remote heat transfer fins are preferably positioned adjacent to the left side panel of the first tray. In a still further option, the heat sink assembly may include third and fourth heat pipes, wherein the third heat pipe includes a first end connected to the heat sink and a second end connected to the first set of remote heat transfer fins, and wherein the fourth heat pipe includes a first end connected to the heat sink and a second end connected to the second set of remote heat transfer fins. Optionally, each heat pipe may contain a volatile liquid and a wicking material, such that the volatile liquid is vaporized at the first end of the heat pipe when exposed to the heat produced by the processor and condensed back to the liquid state at the second end of the heat pipe when air flow across the remote heat transfer fins cools the vapor. The wicking material causes the liquid at the second end of the heat pipe to be drawn back to the first end of the heat pipe to repeat the cycle. In some embodiments, the second end of the first and second heat pipes has an elevation greater than an elevation of the first system board, and the second end of the third and fourth heat pipes has an elevation less than the elevation of the first system board. Furthermore, any number of heat pipes could be used in the disclosed manner extending from the heat sink to a set of remote heat transfer fins.

In some embodiments, the apparatus further comprises a 2U chassis including a power bay, a fan bay, and first and second sled bays positioned side-by-side in front of the fan bay and power bay. The fan bay includes a plurality of fans directed to draw airflow into the front of the chassis and out the rear of the chassis, such that air moves across the components of the first sled, specifically including the heat sink, the first and second sets of remote heat transfer fins, and the first and second sets of memory modules. In a preferred embodiment, the 2U chassis is receivable in a nominal 19-inch wide rack and the first tray is receivable in the first sled bay.

In some embodiments, the memory module sockets may have uniform pitch. As used herein, the term “pitch” refers to the distance between one point on a first memory module socket and the corresponding point on the next/adjacent memory module socket on the same side of the system board (i.e., top or bottom) and the same lateral side of the processor (i.e., left or right of the processor). So, the pitch may be the distance from the center of one memory module socket to the center of the next memory module socket. In one option, the first and second sets of memory module sockets may have a pitch greater than or equal to 297 mils (0.297 inch). This distance is important so that the airflow through the chassis is able to adequately cool the memory modules that are installed in the memory module sockets. It is a technical advantage of various embodiments that the positioning of memory module sockets on both the top and bottom of the system board enables the pitch of the memory module sockets to be maintained greater than or equal to 297 mils on a narrow system board that is approximately half the width of a standard system board for a 19-inch chassis.

In some embodiments, the first and second sled bays have the same width. Accordingly, a sled may be independently received in either of the sled bays. Furthermore, first and second sleds may be received in the first and second sled bays.

In some embodiments, the apparatus may further comprise a second sled. Accordingly, the apparatus may further comprise a second system board having a top surface and a bottom surface, a second processor socket positioned on the top surface of the second system board, a third set of memory module sockets positioned on the top surface of the second system board, and a fourth set of memory module sockets positioned on the bottom surface of the second system board. The second processor socket is connected to each of the memory module sockets in the third and fourth sets of memory module sockets by a memory channel. Still further, the apparatus comprises a second processor installed in the second processor socket, a third plurality of dual in-line memory modules installed in the third set of memory module sockets, and a fourth plurality of dual in-line memory modules installed in the fourth set of memory module sockets. In addition, the apparatus comprises a second tray having a bottom panel, a right side panel and a left side panel, wherein the second system board is positioned between the right and left side panels of the second tray and is secured to the bottom panel of the second tray using a second plurality of spacers that position the second system board above the bottom panel of the second tray at a distance that accommodates the fourth plurality of dual in-line memory modules installed in the fourth set of memory module sockets.

In some embodiments, the apparatus may further comprise a system midplane disposed in the chassis. The system midplane includes a first forward-facing connector for coupling with the first system board and a second forward-facing connector for coupling with the second system board, wherein the system midplane supports communication between the first and second sleds. For example, where the first and second sleds both comprise a computer, the system midplane may enable communication between the computers operating as separate nodes or support operation of the computers as a single node. In alternative embodiments, one or more cables may be connected between the sleds rather than using a system midplane. For example, the apparatus may further comprise a processor interconnect cable connected between the first and second system boards to support operation of the two computers or sleds as a single node.

In some embodiments, the apparatus may further comprise a second tray including a plurality of components selected from data storage devices, CXL memory and/or one or more graphics processing units (GPUs)/Accelerators, wherein the second tray is receivable in the second sled bay, and wherein the plurality of components are connectable to the first system board. For example, one or more of the components of the second sled or tray may be similar to add-in cards and may be connected to the first system board using PCIe cables.

Some embodiments may support CPU performance (500+W), memory topology (16 channels), and high memory bandwidth performance in a dense computing environment. Accordingly, embodiments may support high performance computing (HPC), such as Enterprise Artificial Intelligence (AI) and machine learning/deep learning (ML/DL) with CPU-only inferencing.

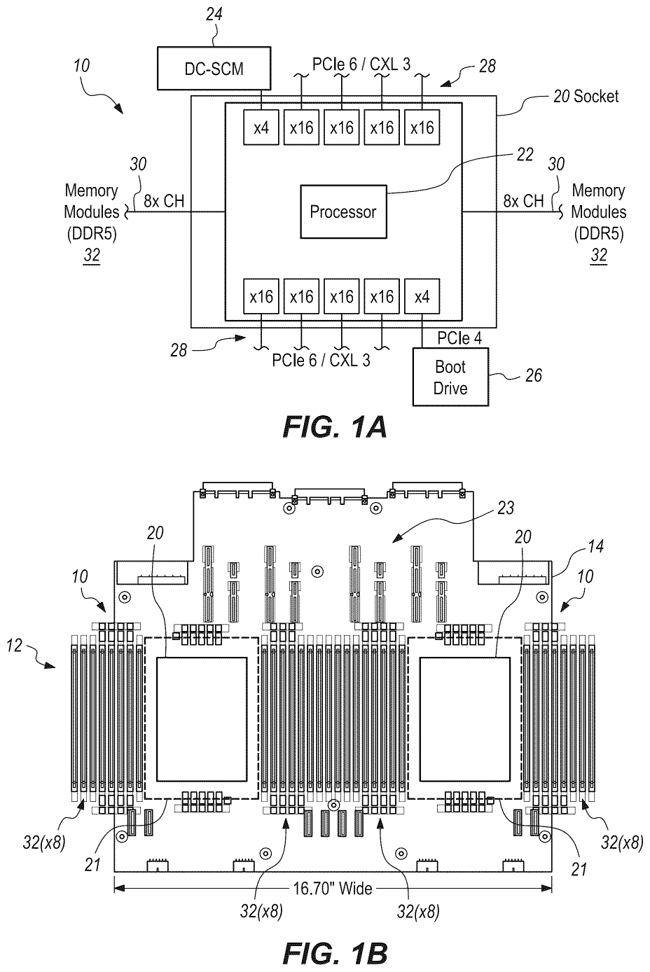

FIG. 1A is a schematic diagram of a computing platform 10 including a processor socket 20 and a processor 22 that support 16 memory channels 30 and expanded input/output capabilities. As shown in this embodiment, the 16 memory channels 30 include 8 memory channels directed to a first lateral side (left) of the processor socket 20 and 8 memory channels directed to a second lateral side (right) of the processor socket 20. The 16 memory channels extend from the processor socket 20 to 16 memory module sockets (not shown) that may each be populated with a memory module 32, such as a Double Data Rate 5 (DDR5) Dynamic Random-Access Memory (DRAM) module. The processor socket 20 also supports connections with a Datacenter Secure Control Module (DC-SCM) 24, a boot drive 26, and numerous Peripheral Component Interconnect Express (PCIe) ports that may support the Compute Express Link (CXL) protocol. In this specific illustration, the processor socket 20 supports 8 PCIe v6.0 standard 16-lane physical interfaces that may utilize the CXL 3.0 protocol for communication with high-bandwidth expansion memory.

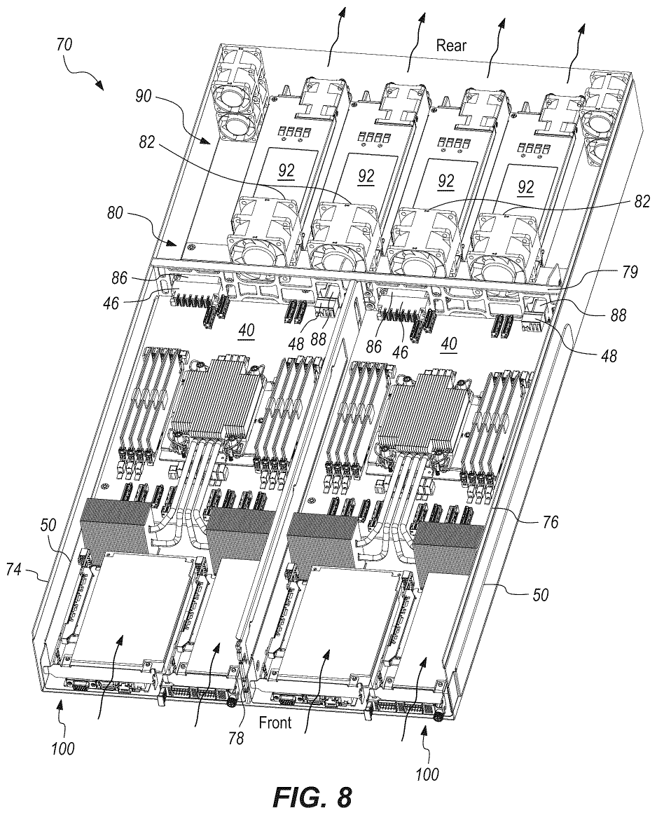

FIG. 1B is a diagram illustrating a dual socket system 12 superimposed over a system board 14 that fits in a 19 inch rack chassis (not shown). The next generation of processors support 16 channels (CHs) of Double Data Rate 5 (DDR5) memory per processor socket 20, in a manner consistent with the computing platform 10 shown in FIG. 1A. However, with the core count continuously going up, the width of the processor socket 20 has also increased. In addition, the Keep-Out Zone (KOZ) 21 for the loading mechanism (LM) has widened from 80 mm to over 100 mm. As a result, two computing platforms 10 having the increased KOZ 21 around the processor and 16 channels of memory having Dual In-Line Memory Modules (DIMMs) 32 with a 297 mil pitch will not fit on the standard system board 14 that fits into a 19″ Electronic Industries Alliance (EIA), EIA-310F Enterprise rack. As illustrated, if the dual processor socket system 12 has 16 channels of memory per processor and the memory module sockets have a 350 mil pitch, then five memory module sockets on the left and five memory module sockets on the right would not fit on the system board 14. Fitting such a dual processor socket system 12 on a single system board would require a system board that is about 20 inches wide, which fits into an Open Compute Project (OCP) Open Rack version 3(ORv3 ) 21″ rack. This is not acceptable for the Enterprise market, as datacenters cannot upgrade their entire floor with cloud-like infrastructure. Furthermore, while a system board with a smaller pitch between memory module sockets could be physically configured, the pitch would need to be as small as about 255 mils. Unfortunately, thermal simulations on a system with a 255 mil memory module pitch show that this configuration is not a feasible solution as the temperature of the preheated air going into the downstream Peripheral Component Interconnect Express (PCIe) Add-in Card (AIC) area 23 and Power Supply Unit (PSU) areas (not shown; but see FIG. 8) is too high (i.e., about 10% greater than the acceptable 55-60° C. range). For example, the power supply units (PSUs) will trip at temperatures over 60° C. Furthermore, it is foreseeable that an end user will want to install MRDIMMs, or other types of memory modules, that may consume up to 22 W of power rather than the average 14 W of power consumption.

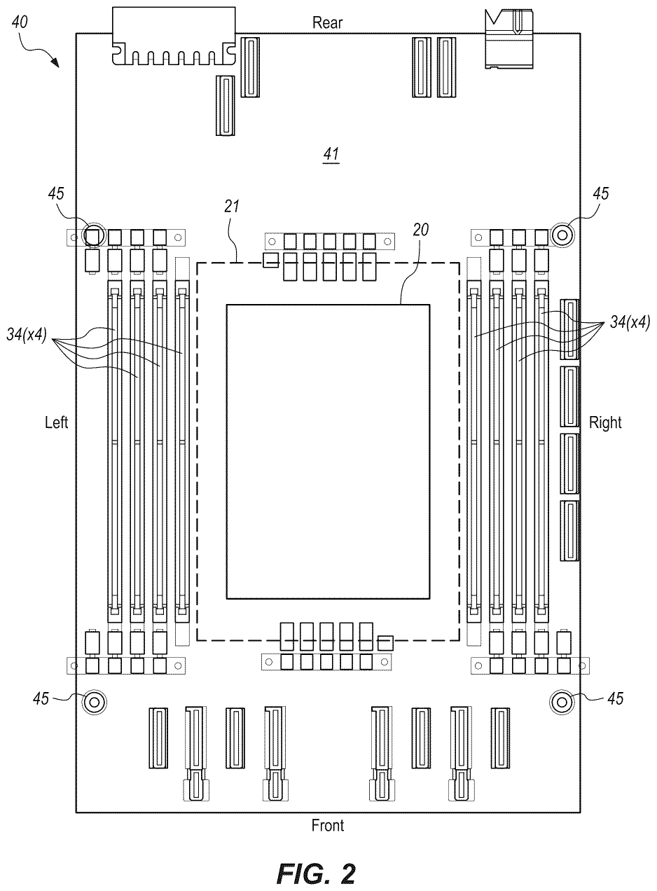

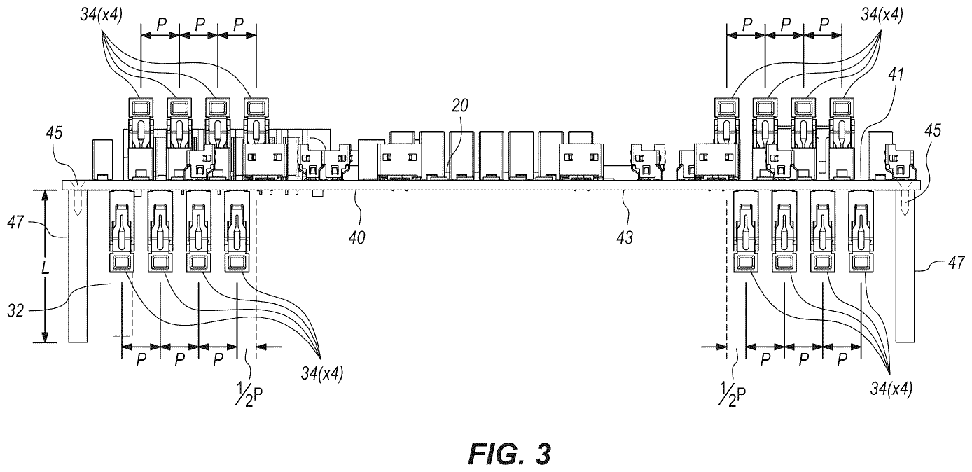

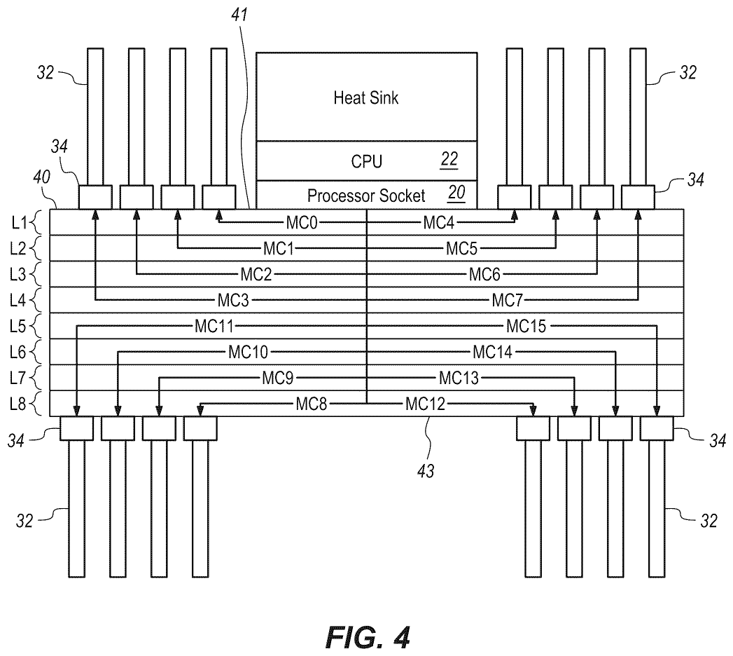

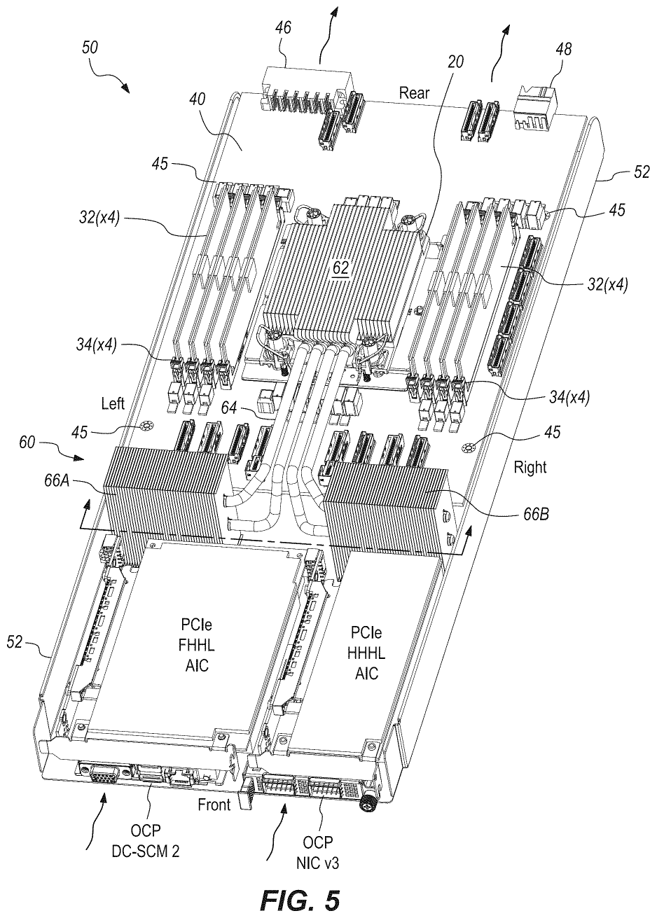

FIG. 2 is a plan view of a single socket system board 40 supporting 16 memory channels/memory sockets per processor socket 20, including 8 memory module sockets 34 on the top surface 41 of the system board 40 and 8 memory module sockets on the bottom surface (not shown; but see FIG. 3) of the system board 40. The processor socket 20 is in the middle of the system board with four memory module sockets 34 on either lateral side (left and right in FIG. 2). Notice the positions of four fasteners 45 that extend through the system board 40 to secure the system board to spacers (not shown; see FIG. 3) in a tray (not shown; see FIG. 5). A processor (not shown; see FIG. 1A) will be installed in the processor socket 20 and a first plurality of dual in-line memory modules 32 (not shown; but see FIG. 3) will be installed in the first set of memory module sockets. A second plurality of dual in-line memory modules (not shown; but see FIGS. 4-5) will be installed in the second set of memory module sockets (not shown; but see FIG. 3) on the bottom side of the system board 40.

FIG. 3 is a front end view of the single socket system board 40 of FIG. 2 showing the bottom memory module sockets 34 (a second set of memory module sockets) that are positioned on the bottom surface 43 of the system board offset from the top memory module sockets 34 (a first set of memory module sockets) that are positioned on the top surface 41 of the system board. In the illustrated embodiment, there is an equal number of memory module sockets on the top surface 41 and the bottom surface 43. Accordingly, half of the memory module sockets 34 are in the first set (i.e., 8 DIMM sockets) on the top surface 41 and half of the memory module sockets 34 are in the second set (i.e., 8 DIMM sockets) on the bottom surface 43. In this configuration, all 16 channels of memory can fit on a 210 mm (8.3 inch) wide system board 40. Furthermore, two of the illustrated system boards 40 can fit in their own tray (not shown; see FIG. 5) and these trays can fit side-by-side into a multi-node chassis (see FIG. 8) compatible with a 19″ EIA rack (not shown). Instead of packing the memory modules so close together that they can't be cooled adequately, positioning memory modules on both sides of the system board allows a memory module pitch “P” of 370 mils (0.370 inch; illustrated as the distance from centerline to centerline), which can easily be cooled with air (axial force convection fans; see FIG. 8) or liquid-cooled with water (cold plates, pumps, and Coolant Distribution Units (CDUs)). The memory module pitch (P) may be any value in the range of 297 to 400 mils, but a preferred pitch is (as shown) about 370 mils.

Notice that the individual memory module sockets 34 that are on the top surface 41 of the system board are laterally offset (left-right in FIG. 3) from the individual memory module sockets 34 on the bottom surface 43 of the system board. Specifically, the memory module DIMM socket connector forks or solder tabs (not shown) that protrude into the system board from the top surface 41 of the system board should miss the adjacent memory module socket connector forks or solder tabs (not shown) that protrude into the system board from the bottom surface 43 of the system board. Preferably, the memory module sockets 34 on the bottom surface are laterally offset by half the pitch (1/2 P) of the memory module sockets 34 on the top of the system board. Also shown is a pair of the fasteners 45 securing the system board 40 to a pair of spacers 47 having a length L that is longer than a memory module 32 (shown in dashed lines) will extend downward from the bottom surface 43.

FIG. 4 is a schematic diagram illustrating the routing of 16 memory channels from the processor socket 20 to each of the 16 memory module sockets 34. As shown, a first set of memory module sockets 34 on the top surface 41 include eight memory module sockets, the second set of memory module sockets 34 on the bottom surface 43 include eight memory module sockets, and the processor socket 20 is connected to the memory module sockets 34 in the first and second sets of memory module sockets by sixteen memory channels (MC1 to MC16). Accordingly, each memory module socket may be connected to the first processor socket by a separate one of the memory channels.

In the illustrated embodiment, the system board 40 includes 8 memory routing layers (L1 to L8). Each memory channel (MC0 to MC15) is connected from the processor socket 20 to one of the memory module sockets 34 by routing through one of the memory routing layers of the system board. For example, four of the memory module sockets 34 in the first (top) set may be positioned on a first (left) lateral side of the first processor socket 20, four of the memory module sockets 34 in the first (top) set may be positioned on a second (right) lateral side of the first processor socket 20 that is opposite of the first (left) lateral side of the processor socket 20, four of the memory module sockets 34 in the second (bottom) set may be positioned on the first (left) lateral side of the first processor socket 20, and four of the memory module sockets 34 in the second (bottom) set may be positioned on the second (right) lateral side of the first processor socket.

The system board may have any number of layers, such as 22 layers, although only eight memory routing layers (L1 to L8) are shown. Here, there are two memory module sockets 34 per memory routing layer, including one memory module socket on the left of the processor socket and one memory module socket on the right of the processor socket. One non-limiting arrangement of the memory channels provides a first routing layer L1 routing two memory channels MC0 and MC4 to one top socket 34 on each side (left and right) of the processor socket 20, a second routing layer L2 routing two memory channels MC1 and MC5 to one top DIMM socket on each side of the processor socket, a third routing layer L3 routing two memory channels MC2 and MC6 to one top socket 34 on each side (left and right) of the processor socket 20, a fourth routing layer L4 routing two memory channels MC3 and MC7 to one top DIMM socket on each side of the processor socket, a fifth routing layer L5 routing two memory channels MC11 and MC15 to two bottom DIMM sockets one each side of the processor socket, and a sixth routing layer L6 routing four memory channels MC10 and MC14 to two bottom DIMM sockets on each side of the processor socket, a seventh routing layer L7 routing two memory channels MC9 and MC13 to two bottom DIMM sockets one each side of the processor socket, and a eighth routing layer L8 routing four memory channels MC8 and MC12 to two bottom DIMM sockets on each side of the processor socket.

FIG. 5 is a perspective view of a single sled 50 including the system board 40, a heat sink assembly 60 and other supporting components secured in a tray 52. The tray 52 may, for example, be made of metal and forms the base of the sled 50 to support the system board and other components within the tray. It may be common for a sled to be referred to as a node, but the term “node” more particularly relates to software and implies that there is a single operating system. For example, the system boards of two sleds could be connected by a processor interconnect to operate as a single 2S node requiring only a single operating system instance, yet the same two sleds without such a connection, or with such a connection disabled, could operate as two 1S nodes with two separate operating system instances.

The system board 40 is consistent with the system board shown in FIGS. 2-4, but the processor (not shown) and the memory modules 32 have been installed. Furthermore, the system board 40 has been secured in the tray 52 at four points using fasteners 45 that extend into spacers 47 (see FIG. 3) that position the system board 40 at a mid-point elevation in a 2U chassis (not shown; see FIG. 8). The sled 50 also includes the heat sink assembly 60 that forms a self-contained, closed loop liquid cooling system. This heat sink assembly 60 include a local heat sink 62 with its own fins directly above the processor socket 20 as well as heat pipes 64 (four shown) that extend from the heat sink 62 to two sets of remote fins 66A and 66B. The two sets of remote fins 66A and 66B are preferably positioned upstream (to the front) of the front edge of the system board 40 so that the heat exchange area of the remote fins 66A and 66B may extend most of the way from the top of a sled bay in a 2U chassis to the bottom of the tray 52. Using sets of double-height remote fins 66A and 66B, the heat sink assembly 60 can provide a greater amount of cooling than can be provided in a 1U chassis. For example, existing heat pipe heat sinks, which may be referred to as Liquid-Assisted Air Cooling (LAAC), Liquid-Enhanced Air Cooling (LEAC) or Liquid to Air (L2A), installed in a 1U chassis must be positioned entirely above the system board, such that the remote fins are limited to less than a 1U of height or even less than a ½U of height. Unfortunately, remote fins with less than 1U or less than ½U of height are not adequate to cool processors with high heat dissipation values greater than 500 W.

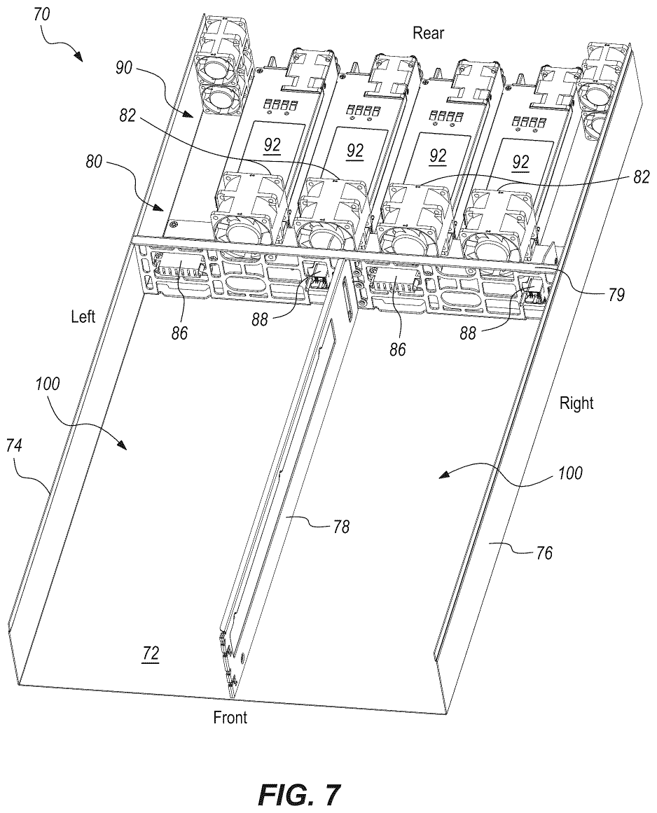

In some embodiments, each sled may further a management module such as an OCP Datacenter Secure Control Module (DC-SCM) an OCP network interface controller (NIC) v3, some 2.5″ hard disk drives (HDDs) or solid state drives (SSDs) for storage, or Enterprise Datacenter Standard Form Factor (EDSFF) E3.S 1T or 2T modules for storage or CXL memory, storage backplane(s), some PCIe adapter cards such as the PCIe FHHL (Full height, half length) AIC (Add-in-Card) and/or the PCIe HHHL (Half height, half length) AIC, High-Speed Input/Output (HSIO) cabling to connect these devices to the motherboard. Each sled 50 also includes a pair of rear connectors, including a rear facing power connector 46 and a rear facing input/output connector 48. These connectors 46, 48 support the operation of the sled 50 within the chassis. Further description of these connectors 46, 48 is provided in reference to FIGS. 7-10 below.

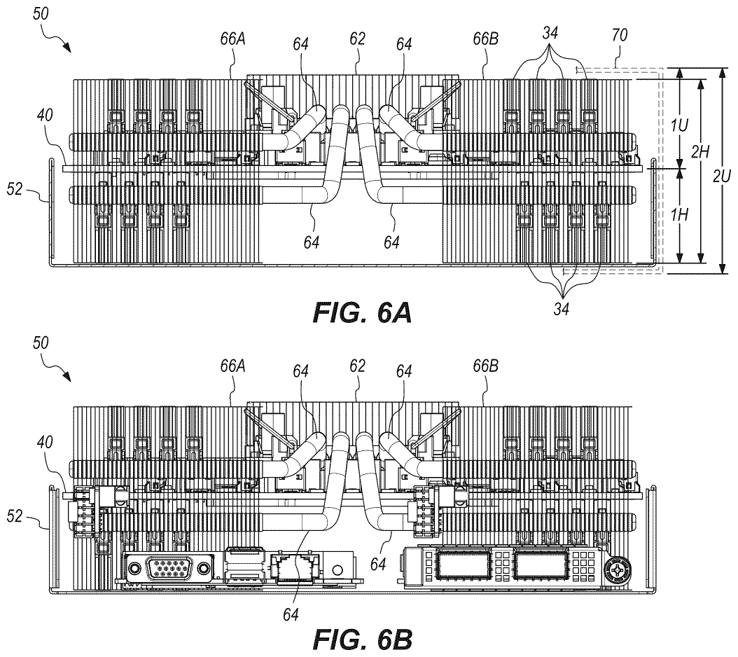

FIG. 6A is a cross-section view of the sled 50 taking along lines 6A-6A in FIG. 5. The sets of remote fins 66A and 66B are the full height (i.e., double height 2H) of the compute system secured in the tray 52 (including the bottom DIMMs 34, system board 40, and top DIMMs 34). The term “double height” (2H) refers to the usable space available in a 2U sled bay after accounting for the thickness of the 2U chassis 70 (partially shown in dashed lines) and tray 52. A rack unit (U) is a unit of measure based on a rack specification described by the Electronic Industries Alliance (EIA) as standard EIA-310. Each rack unit (U) is about 1.75 inches (44.45 mm). Individual components that are mounted in a rack may have a height of 1U, 2U, 3U, etc. The rack width is typically either 19 inches or 23 inches.

However, it should be recognized that components contained within a chassis cannot be the full height of the chassis. In recognition that the chassis top and bottom walls themselves occupy some of the 2U height, as does the tray received into the chassis, as well as the fact that components might be designed to avoid actually contacting the sides of the tray or chassis, components may be described as being “double-height” (2H) if they occupy a substantial portion of the vertical distance available within a 2H chassis and/or tray. Still, it is common to refer to a node that goes into a 2U two-node (2U2N) chassis as being a 2U node, or to refer to a node that goes into a 2U four-node (2U4N) chassis as being a 1U node. However, as used herein, the term “node” refers to a computing system running with a single operating system, whereas the term “sled” refers to a self-contained system that may be received into a sled bay of a chassis.

In reference to FIG. 6A, the four heat pipes 64 extend from the processor heat sink 62 to the remote fins 66A and 66B. As shown, two of the four copper heat pipes 64 extend below the level of the system board 40 before passing through the two sets of remote fins 66A and 66B to the left or right. The other two copper heat pipes 64 remain above the level of the system board 40 as they extend to the two sets of remote fins 66A and 66B to the left or right.

Heat generated by the processor operating within the processor socket will vaporize a liquid (usually alcohol) inside the first end of the heat pipes 64. The vapor is carried within the heat pipes to the remote fins 66A and 66B where the vapor condenses back to liquid due to the transfer of heat through the remote fins and ultimately into the air that flows across the surfaces of the remote fins and then across the surfaces of the memory modules (instead of the processor). The liquid within the heat pipes is then drawn back to the main heat sink over the processor socket to repeat the cycle or process. The heat pipe may use a capillary effect to transfer the liquid through the heat pipes from the remote fins back to the processor socket heat exchanger. It is a significant advantage that the remote fins 66A and 66B may extend across the entire available height 2H within the 2U sled bay.

FIG. 6B is a front end view of the sled 50. Various other components of the sled 50 may be positioned in front of the remote heat transfer fins 66A and 66B but don't prevent air from flowing through the remote heat transfer fins 66A and 66B and across both the top surface and bottom surface of the system board 40. Also note that since the first and second sets of remote heat transfer fins 66A and 66B are positioned adjacent to the lateral sides of the tray 52, air flow to the heat sink 62 is substantially unimpeded and not warmed by any upstream components. Accordingly, the fins of the heat sink 62 are also able to dissipate a significant portion of the heat generated by the processor.

FIG. 7 is a perspective view of a chassis 70 with a top panel removed to reveal a fan bay or area 80, a power bay or area 90 and two sled bays 100. The chassis 70 includes a floor panel 72, a left side panel 74, a right side panel 76, a sled bay divider 78, and a cross-chassis support 79. The fan bay 80 includes a plurality of rotary fans 82 for moving air through the 2U chassis 70 from the front to the rear. Optionally, the fans 82 may be dual-rotor, counter-rotating fans. The power bay 90 includes power supplies 92 for supply power to the fans 82 and the sleds 50 (not shown; see FIG. 8). As shown, the power bay 90 includes four power supply units (PSUs) 92 to provide full redundancy (N+N redundancy). Each of the PSUs 92 may have their own single-rotor or dual-rotor fan. For example, high-power PSUs capable of supplying greater than 2 kW may include high-performance fans, such as 40×56 mm dual-rotor fans.

The left side panel 74, the sled bay divider 78 and the floor panel 72 cooperate to delineate a first sled bay and provide surfaces that guide a sled into an installed position. Specifically, a rear portion of a sled may be inserted into the front of the sled bay 100 and pushed into the sled bay until the sled is fully received into the sled bay, such as when front of the sled is generally even with the front of the sled bay. If a midplane were provided along the cross-chassis support 79, then a rear-facing connector on the sled may blind-mate with a forward facing connector on the midplane to establish electronic communication. Most importantly, the sled should be pushed into the sled bay 100 until the rear-facing connector 46, 48 on the sled 50 (see FIG. 5) connect (i.e., blind-mate) with mating forward facing power and communication connectors 86, 88 secured to the cross-chassis support 79. These connections are shown in reference to FIG. 8, below. A similar second sled bay is formed by the sled bay divider 78, the right side panel 76, and the floor panel 72.

FIG. 8 is a perspective view of the chassis 70 of FIG. 7 after two sleds 50 of FIG. 5 have been installed within the two sled bays 100. The two sleds may operate as a single node or as two independent nodes. Each sled 50 obtains its power from one or more of the power supplies 92 in the power bay 90 and receives air flow from front to rear caused by the fans 82 in the fan bay 80.

In some embodiments, the two sleds 50 may, without limitation, be connected by an Intel Ultra Path Interconnect (UPI) or an AMD Socket/Inter-Chip Global Memory Interconnect (xGMI) to form a 2-Socket (2S) system in the 2U chassis 70. For example, each sled 50 may have a rear facing communication connector 48 at the rear edge of the system board 40 for connecting to a forward facing communication connector 88, such as a panel-mounted high density, high speed I/O connector, secured to the cross-chassis support 79. Accordingly, the two sleds 50 may be interconnected for communication with each other and/or to support input/output with a network. Furthermore, each sled 50 may have a rear facing power connector 46 at the rear edge of the system board 40 for connecting to a forward facing power connector 86 secured to the cross-chassis support 79 so that the sled 50 receives power from one or more of the power supplies 92.

The present embodiments, such as that shown in FIG. 8B, change the physical configuration or placement of the memory to be more adaptable to having all 16 channels (16CH) of memory populated within a standard 19″ rack. Instead of a single system board in a single chassis as shown in FIG. 1B, embodiments take advantage of a dual-sled architecture, where there are two system boards that are each disposed within their own tray to form a sled that can be independently inserted and removed from the chassis.

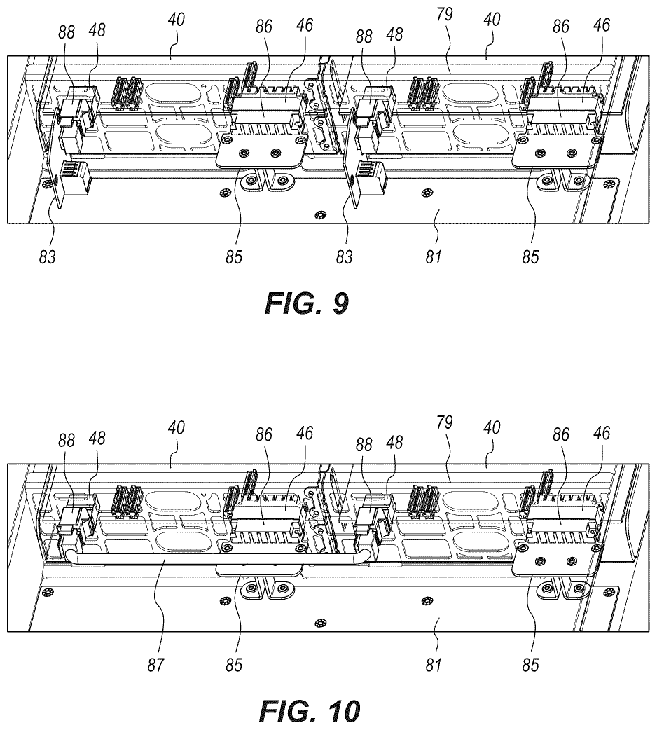

FIG. 9 is a rear perspective view of the interconnections formed between the two sleds (see system boards 40) through a power distribution board (PDB) 81 using vertical backplane boards 83 and the power connection of each sled to the power distribution board 81 using power interposer boards 85 coupled to the power connector 86. For example, the vertical backplane boards 83 may support UPI (Intel) or XGMI (AMD) coherent links that dock into the power distribution board 81 and carry signals (see dashed line) through the power distribution board 81.

FIG. 10 is a rear perspective view of the interconnections formed between the two sleds (see system boards 40) through a panel-mounted cable 87 and the power connection of each sled to the power distribution board 81 using the power interposer boards 85. The panel-mounted cable 87 provides a simpler and shorter route for better signal integrity than using the vertical backplane boards 83 of FIG. 9. In either FIG. 9 or 10, the connectors 88 may each snap into the metal mid-wall or cross-chassis support 79.

The terminology used herein is for the purpose of describing particular embodiments only and is not intended to limit the scope of the claims. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the embodiment.

The corresponding structures, materials, acts, and equivalents of all means or steps plus function elements in the claims below are intended to include any structure, material, or act for performing the function in combination with other claimed elements as specifically claimed. Embodiments have been presented for purposes of illustration and description, but it is not intended to be exhaustive or limited to the embodiments in the form disclosed. Many modifications and variations will be apparent to those of ordinary skill in the art after reading this disclosure. The disclosed embodiments were chosen and described as non-limiting examples to enable others of ordinary skill in the art to understand these embodiments and other embodiments involving modifications suited to a particular implementation.

What is claimed is:

1. A system, comprising:
a first system board having a top surface and a bottom surface;
a first processor socket positioned on the top surface of the first system board;
a first set of memory module sockets positioned on the top surface of the first system board;
a second set of memory module sockets positioned on the bottom surface of the first system board, wherein the first processor socket is connected to each of the memory module sockets in the first and second sets of memory module sockets by a plurality of memory channels corresponding respectively to the memory module sockets;
a first processor installed in the first processor socket;
a first plurality of dual in-line memory modules installed in the first set of memory module sockets; and
a second plurality of dual in-line memory modules installed in the second set of memory module sockets.

2. The apparatus of claim 1, wherein each of the dual in-line memory modules are double data rate 5 memory modules.

3. The apparatus of claim 1, wherein the first set of memory module sockets includes eight memory module sockets, the second set of memory module sockets includes eight memory module sockets, and the first processor socket is connected to the memory module sockets in the first and second sets of memory module sockets by sixteen memory channels.

4. The apparatus of claim 3, wherein the first system board includes eight memory routing layers, and wherein each memory channel between the first processor socket and the first and second sets of memory module sockets is routed in one of the memory routing layers of the first system board.

5. The apparatus of claim 4, wherein four of the memory module sockets in the first set are positioned on a first lateral side of the first processor socket, four of the memory module sockets in the first set are positioned on a second lateral side of the first processor socket that is opposite of the first lateral side of the first processor, four of the memory module sockets in the second set are positioned on the first lateral side of the first processor socket, and four of the memory module sockets in the second set are positioned on the second lateral side of the first processor socket.

6. The apparatus of claim 5, wherein the eight memory routing layers include:
first, second, third and fourth memory routing layers that each route one of the memory channels to one of the memory module sockets in the first set on the first lateral side of the first processor socket and one of the memory channels to one of the memory module sockets in the first set on the second lateral side of the first processor socket; and
fifth, sixth, seventh and eighth memory routing layers that each route one of the memory channels to one of the memory module sockets in the second set on the first lateral side of the first processor socket and one of the memory channels to one of the memory module sockets in the second set on the second lateral side of the first processor socket.

7. The apparatus of claim 1, wherein the second set of memory module sockets are laterally offset from the first set of memory module sockets, and wherein the first and second sets of memory module sockets are positioned on the system board in a pattern alternating between the top and bottom surfaces of the system board with increasing distance from the first processor socket.

8. The apparatus of claim 7, wherein the memory module sockets in the first set of memory module sockets are positioned in parallel with a predetermined pitch on the top surface, the memory module sockets in the second set of memory module sockets are positioned in parallel with the predetermined pitch on the bottom surface, and the second set of memory module sockets are laterally offset from the first set of memory module sockets by a distance of half the predetermined pitch.

9. The apparatus of claim 1, further comprising:
a first tray having a bottom panel, a right side panel and a left side panel, wherein the first system board is positioned between the right and left side panels and secured to the bottom panel of the first tray using a first plurality of spacers that position the first system board above the bottom panel at a distance that accommodates the second plurality of dual in-line memory modules installed in the second set of memory module sockets.

10. The apparatus of claim 9, further comprising:
a heat sink assembly comprising:
a heat sink in thermal contact with the first processor;
first and second sets of remote heat transfer fins; and
first and second heat pipes, wherein the first heat pipe includes a first end connected to the heat sink and a second end connected to the first set of remote heat transfer fins, and wherein the second heat pipe includes a first end connected to the heat sink and a second end connected to the second set of remote heat transfer fins.

11. The apparatus of claim 10, wherein the first and second sets of remote heat transfer fins are positioned in the first tray forward of the system board and include double height fins that extend both above and below the level of the system board, and wherein the first set of remote heat transfer fins are positioned adjacent to the right side panel of the first tray and the second set of remote heat transfer fins are positioned adjacent to the left side panel of the first tray.

12. The apparatus of claim 11, further comprising:
third and fourth heat pipes, wherein the third heat pipe includes a first end connected to the heat sink and a second end connected to the first set of remote heat transfer fins, and wherein the fourth heat pipe includes a first end connected to the heat sink and a second end connected to the second set of remote heat transfer fins.

13. The apparatus of claim 12, wherein each heat pipe contains a volatile liquid and a wicking material, wherein the second end of the first and second heat pipes has an elevation greater than an elevation of the system board, and wherein the second end of the third and fourth heat pipes has an elevation less than the elevation of the system board.

14. The apparatus of claim 9, further comprising:
a 2U chassis including a power bay, a fan bay, and first and second sled bays positioned side-by-side in front of the fan bay and power bay, wherein the fan bay includes a plurality of fans directed to draw airflow into the front of the chassis and out the rear of the chassis, wherein the chassis is receivable in a nominal 19 inch wide rack, and wherein the first tray is receivable in the first sled bay.

15. The apparatus of claim 14, wherein the first set of memory module sockets have a pitch greater than 297 mils and the second set of memory module sockets have a pitch greater than 297 mils.

16. The apparatus of claim 14, wherein the first and second sled bays have the same width.

17. The apparatus of claim 16, further comprising:
a second system board having a top surface and a bottom surface;
a second processor socket positioned on the top surface of the second system board;
a third set of memory module sockets positioned on the top surface of the second system board;
a fourth set of memory module sockets positioned on the bottom surface of the second system board, wherein the second processor socket is connected to each of the memory module sockets in the third and fourth sets of memory module sockets by a memory channel;
a second processor installed in the second processor socket;
a third plurality of dual in-line memory modules installed in the third set of memory module sockets;
a fourth plurality of dual in-line memory modules installed in the fourth set of memory module sockets; and
a second tray having a bottom panel, a right side panel and a left side panel, wherein the second system board is positioned between the right and left side panels of the second tray and is secured to the bottom panel of the second tray using a second plurality of spacers that position the second system board above the bottom panel of the second tray at a distance that accommodates the fourth plurality of dual in-line memory modules installed in the fourth set of memory module sockets.

18. The apparatus of claim 17, further comprising:
a system midplane disposed in the chassis, the system midplane having a first forward-facing connector for coupling with the first system board and a second forward-facing connector for coupling with the second system board, wherein the system midplane supports communication between the first and second sleds.

19. The apparatus of claim 17, further comprising
a processor interconnect cable connected between the first and second system boards to support operation as a single node.

20. The apparatus of claim 14, further comprising:
a second tray including a plurality of components selected from data storage devices, CXL memory and/or one or more graphics processing units or accelerators, wherein the second tray is receivable in the second sled bay, and wherein the plurality of components are connectable to the first system board.
